(19) United States
(12) Patent Application Publication
(10) Pub. No.: US 2006/0137612 A1
(43) Pub. Date: Jun. 29, 2006

(54) Methods and apparatus for downstream dissociation of gases

(75) Inventors: William M. Holber, Winchester, MA (US); Xing Chen, Lexington, MA (US)

Correspondence Address: PROSKAUER ROSE LLP, ONE INTERNATIONAL PLACE 14TH FL, BOSTON, MA, 02110, US

(73) Assignee: MKS Instruments, Inc., Wilmington, MA (US)

(21) Appl. No.: 11/292,520

(22) Filed: Dec. 2, 2005

Related U.S. Application Data
(63) Continuation-in-part of application No. 11/003,109, filed on Dec. 3, 2004.

(51) Int. Cl. C23C 16/00; C23F 1/00

(52) U.S. Cl. 118/723 R; 427/248.1; 156/345.35; 118/715

(57) ABSTRACT

A method and apparatus for activating and dissociating gases involves generating an activated gas with a plasma located in a chamber. A downstream gas input is positioned relative to an output of the chamber to enable the activated gas to facilitate dissociation of a downstream gas introduced by the gas input, wherein the dissociated downstream gas does not substantially interact with an interior surface of the chamber.

### RELATED APPLICATIONS

This application is a continuation-in-part of prior application Ser. No. 11/003,109, filed on Dec. 3, 2004 the entire disclosure of which is incorporated by reference herein.

### FIELD OF THE INVENTION

The invention relates to methods and apparatus for activating gases. More particularly, the invention relates to methods and apparatus for generating dissociated gases and apparatus for and methods of processing materials with dissociated gases.

### BACKGROUND OF THE INVENTION

Plasmas are often used to activate gases placing them in an excited state such that the gases have an enhanced reactivity. Excitation of a gas involves elevating the energy state of the gas. In some cases, the gases are excited to produce dissociated gases containing ions, free radicals, atoms and molecules. Dissociated gases are used for numerous industrial and scientific applications including processing solid materials such as semiconductor wafers, powders, and other gases. The parameters of the dissociated gas and the conditions of the exposure of the dissociated gas to the material being processed vary widely depending on the application. Significant amounts of power are sometimes required in the plasma for dissociation to occur.

Plasma sources generate plasmas by, for example, applying an electric potential of sufficient magnitude to a plasma gas (e.g., O₂, N₂, Ar, NF₃, H₂ and He), or a mixture of gases, to ionize at least a portion of the gas. Plasmas can be generated in various ways, including DC discharge, radio frequency (RF) discharge, and microwave discharge. DC discharge plasmas are achieved by applying a potential between two electrodes in a plasma gas. RF discharge plasmas are achieved either by electrostatically or inductively coupling energy from a power supply into a plasma. Microwave discharge plasmas are achieved by directly coupling microwave energy through a microwave-passing window into a discharge chamber containing a plasma gas. Plasmas are typically contained within chambers that are composed of metallic materials such as aluminum or dielectric materials such as quartz.

There are applications in which an activated gas may not be compatible with the plasma source. For example, during semiconductor manufacturing, atomic oxygen is reacted with a photoresist to remove photoresist from a semiconductor wafer by converting the photoresist to volatile CO₂ and H₂O byproducts. Atomic oxygen is typically produced by dissociating O₂ (or a gas containing oxygen) with a plasma in a plasma chamber of a plasma source. The plasma chamber is typically made of quartz because of the low surface recombination rate of atomic oxygen with quartz. Atomic fluorine is often used in conjunction with atomic oxygen because the atomic fluorine accelerates the photoresist removal process. Fluorine is generated by, for example, dissociating NF₃ or CF₄ with the plasma in the plasma chamber. Fluorine, however, is highly corrosive and may adversely react with the quartz chamber. Under similar operating conditions, use of a fluorine compatible chamber material (e.g., sapphire or aluminum nitride) reduces the efficiency of atomic oxygen generation and increases the cost of processing because fluorine compatible materials are typically more expensive than quartz.

Another application in which an activated gas is not compatible with a plasma chamber material involves a plasma comprising hydrogen located within a quartz chamber. Excited hydrogen atoms and molecules may react with the quartz (SiO₂) and convert the quartz to silicon. Changes in the material composition of the chamber may, for example, result in undesirable drift of the processing parameters and also in the formation of particles. In other applications, the quartz may be converted into Si₃N₄ if nitrogen is present in the plasma chamber during processing.

A need therefore exists for effectively dissociating a gas with a plasma in a manner that minimizes adverse effects of the dissociated gas on the plasma chamber.

### SUMMARY OF THE INVENTION

The invention, in one aspect, relates to a method for activating and dissociating gases. The method involves generating an activated gas with a plasma in a chamber. The method also involves positioning a downstream gas input relative to an output of the plasma chamber to enable the activated gas to facilitate dissociation of a downstream gas introduced by the downstream gas input, wherein the dissociated downstream gas does not substantially interact with an interior surface of the plasma chamber.

In some embodiments, the plasma can be generated by a remote plasma source. The remote plasma source can be, for example, an RF plasma generator, a microwave plasma generator or a DC plasma generator. The plasma can be generated from, for example, oxygen, nitrogen, helium or argon. The downstream gas can include a halogen gas (e.g., NF₃, CF₄, CHF₃, C₂F₆, C₂HF₅, C₃F₈, C₄F₈, XeF₂, Cl₂ or ClF₃). The downstream gas can include fluorine. An interior surface of the chamber can include, for example, a quartz material, sapphire material, alumina, aluminum nitride, yttrium oxide, silicon carbide, boron nitride, or a metal such as aluminum, nickel or stainless steel. An interior surface of the chamber can include, for example, a coated metal (e.g., anodized aluminum). In some embodiments, alternative gases may be used as the downstream gas, for example, H₂, O₂, N₂, Ar, H₂O, and ammonia. In some embodiments, the downstream gas includes one or more gases that comprise metallic materials or semiconductor materials to be deposited on, for example, a substrate. The metallic or semiconductor materials can include, for example, Si, Ge, Ga, In, As, Sb, Ta, W, Mo, Ti, Hf, Zr, Cu, Sr or Al. In some embodiments, the downstream gas includes one or more gases that comprise metallic or semiconductor materials, or oxides or nitrides comprising the metallic or semiconductor materials. In some embodiments, the downstream gas includes hydrocarbon materials.

The downstream gas can be introduced into the chamber at a variety of locations. In some embodiments, the downstream gas can be introduced at a location relative to the output of the chamber that minimizes the interaction between the dissociated downstream gas and the interior surface of the chamber. The downstream gas can be introduced at a location relative to the output of the chamber that maximizes the degree to which the downstream gas is dissociated. The downstream gas can be introduced at a location relative to the output of the chamber that balances the degree to which the dissociated downstream gas interacts with the interior surface of the chamber with the degree to which the downstream gas is dissociated. The dissociated downstream gas can be used to facilitate etching or cleaning of or deposition onto a substrate.

To help protect the surface of the plasma chamber, a barrier (e.g., shield or liner) can be installed near the outlet of the plasma chamber and the downstream gas input. The barrier can be made of a material that is chemically compatible with the reactive gases. In some embodiments, the barrier is removable, allowing for periodic replacement. The barrier can be made of a material that is substantially resistant to the reactive gases. The barrier can be or comprise, for example, a sapphire material that is located at the outlet of the plasma chamber. The barrier can be located partially within the plasma chamber.

In some embodiments, the barrier can be or comprise a ceramic material (e.g., sapphire, quartz, alumina, aluminum nitride, yttrium oxide, silicon carbide, or boron nitride). The barrier can also be made of a material that has a low surface recombination rate or reaction rate with the dissociated downstream gases so that the transport efficiency of the dissociated gases to the substrate can be improved. Materials with low recombination properties include, for example, quartz, diamond, diamond-like-carbon, hydrocarbon, and fluorocarbon. The barrier can be made of a metal, such as aluminum, nickel or stainless steel. The type of metal may be selected based upon desired mechanical and thermal properties of the metal.

The surface of the barrier (e.g., shield or liner) can be coated with a layer of chemically compatible or low surface recombination/reaction materials. The barrier can also be made with a material that reacts with the dissociated downstream gas. For example, in some applications a barrier that is slowly consumed is actually desirable as it may avoid build up of contamination or particles. The barrier can be located partially within the plasma chamber. To reduce adverse interaction between dissociated downstream gas and the plasma chamber, additional purge gas can be introduced between the outlet of the plasma chamber and the downstream gas injection input.

The method also can involve specifying a property (e.g., one or more of pressure, flow rate and distance injected from the output of the chamber) of the downstream gas to optimize dissociation of the downstream gas. The method also can involve specifying a property (e.g., one or more of pressure, flow rate, gas type, gas composition and power to the plasma) of the plasma gas to optimize dissociation of the downstream gas.

In another aspect, the invention relates to a method for activating and dissociating gases that involves generating an activated gas with a plasma in a chamber. The method also involves introducing a downstream gas into the activated gas external to the chamber at a location sufficiently close to an output of the chamber such that the activated gas has an energy level sufficient to facilitate excitation (e.g., dissociation) of the downstream gas. The location is sufficiently spaced from the output of the chamber such that the excited downstream gas does not substantially interact with an interior surface of the chamber.

In another aspect, the invention relates to a method for etching photoresist. The method involves generating an activated gas with a plasma located in a chamber. The method also involves combining a downstream gas with at least a portion of the activated gas such that the activated gas comprises an energy level sufficient to facilitate excitation (e.g., dissociation) of the downstream gas and such that the excited downstream gas does not substantially interact with an interior surface of the chamber. The method also involves etching a substrate with the dissociated downstream gas. The method also may involve cleaning a surface with the dissociated downstream gas. The method also may be used to deposit materials on a substrate. The method also may be used to produce powders.

In another aspect, the invention relates to a method for activating and dissociating gases. The method involves generating an activated gas with a plasma in a chamber. The method also involves introducing a downstream gas to interact with the activated gas outside a region defined by the plasma to enable the activated gas to facilitate excitation (e.g., dissociation) of the downstream gas, wherein the excited gas does not substantially interact with an interior surface of the chamber.

The invention, in one embodiment, features a system for activating and dissociating gases. The system includes a plasma source for generating a plasma in a chamber, wherein the plasma generates an activated gas. The system also includes means for combining at least a portion of the activated gas with a downstream gas to enable the activated gas to facilitate excitation (e.g., dissociation) of the downstream gas, wherein the excited downstream gas does not substantially interact with an interior surface of the chamber. In some embodiments, interactions between the activated gas and the downstream gas facilitate ionization of the downstream gas. The transfer of energy from, for example, the activated gas to the downstream gas increases chemical reactivity of the downstream gas.

The invention, in another aspect, relates to apparatus and method for dissociating halogen-containing gases (e.g., NF₃, CHF₃ and CF₄) with a plasma activated gas at a location downstream of a plasma chamber without substantial interaction (e.g., erosion) of the halogen gases with the plasma chamber walls.

The invention, in another embodiment, features a system for activating and dissociating gases. The system includes a remote plasma source for generating a plasma region in a chamber, wherein the plasma generates an activated gas. The system also includes an injection source for introducing a downstream gas to interact with the activated gas outside the plasma region, wherein the activated gas facilitates excitation (e.g., dissociation) of the downstream gas, and wherein the excited downstream gas is dissociated downstream gas and does not substantially interact with an interior surface of the chamber.

The system can include a barrier located at an output of the chamber to reduce erosion of the chamber. The barrier can be located, for example, partially within the chamber. The barrier can be located, for example, partially within an output passage of the chamber. The system can include a barrier located within an output passage of the chamber. The system can include a mixer to mix downstream gas and activated gas. The mixer can include a static flow mixer, a helical mixer, blades, or a stacked cylinder mixer. The system can include a purge gas input. The purge gas input can be located between an outlet of the chamber and an input of the injection source.

The chamber can include a quartz material. In some embodiments, the chamber is a single piece of fused quartz. In some embodiments, the chamber is toroidal-shaped. In some embodiments, the plasma source is a toroidal plasma source.

The invention, in another aspect, relates to a method for depositing a material on a substrate. The method involves generating an activated gas with a plasma in a chamber. The method also involves positioning a downstream gas input relative to an output of the plasma chamber to enable the activated gas to facilitate dissociation of a downstream gas introduced by the downstream gas input, wherein the downstream gas comprises a material to be deposited, and wherein the dissociated downstream gas does not substantially interact with an interior surface of the plasma chamber.

In some embodiments, the plasma is generated by a remote plasma source. The remote plasma source can be, for example, an RF plasma generator, a microwave plasma generator or a DC plasma generator. The downstream gas can be introduced into the chamber at a variety of locations. In some embodiments, the downstream gas can be introduced at a location relative to the output of the chamber that minimizes the interaction between the dissociated downstream gas and the interior surface of the chamber. The downstream gas can be introduced at a location relative to the output of the chamber that maximizes the degree to which the downstream gas is dissociated. The downstream gas can be introduced at a location relative to the output of the chamber that balances the degree to which the dissociated downstream gas interacts with the interior surface of the chamber with the degree to which the downstream gas is dissociated. The material to be deposited can include one or more of Si, Ge, Ga, In, As, Sb, Ta, W, Mo, Ti, Hf, Zr, Cu, Sr or Al.

The invention, in another aspect, features a system for depositing a material on a substrate. The system includes a remote plasma source for generating a plasma region in a chamber, wherein the plasma generates an activated gas. The system also includes an injection source for introducing a downstream gas, comprising a deposition material, to interact with the activated gas outside the plasma region, wherein the activated gas facilitates excitation (e.g., dissociation) of the downstream gas, and wherein the excited downstream gas does not substantially interact with an interior surface of the chamber.

The material to be deposited can be one or more of Si, Ge, Ga, In, As, Sb, Ta, W, Mo, Ti, Hf, Zr, Cu, Sr or Al. The system can include a mixer to mix downstream gas and activated gas. The mixer can include a static flow mixer, a helical mixer, blades, or a stacked cylinder mixer. The system can include a purge gas input. The purge gas input can be located between an outlet of the chamber and an input of the injection source.

The foregoing and other objects, aspects, features, and advantages of the invention will become more apparent from the following description and from the claims.

### BRIEF DESCRIPTION OF THE DRAWINGS

The foregoing and other objects, feature and advantages of the invention, as well as the invention itself, will be more fully understood from the following illustrative description, when read together with the accompanying drawings which are not necessarily to scale.

FIG. 1 is a partial schematic view of a plasma source for producing dissociated gases that embodies the invention.

FIG. 2A is a cross-sectional view of a gas injection source, according to an illustrative embodiment of the invention.

FIG. 2B is an end view of the gas injection source of FIG. 2A.

FIG. 3A is a cross-sectional view of a gas injection source, according to an illustrative embodiment of the invention.

FIG. 3B is an end-view of the gas injection source of FIG. 3A.

FIG. 4 is a graphical representation of percent dissociation of NF₃ as a function of the distance from the output of a quartz plasma chamber that NF₃ is injected into the plasma source, using a gas dissociation system according to the invention.

FIG. 5 is a graphical representation of percent dissociation of CF₄ as a function of the distance from the output of a quartz plasma chamber that CF₄ is injected into the plasma source, using a gas dissociation system according to the invention.

FIG. 6 is a graphical representation of percent dissociation of NF₃ as a function of the plasma gas flow rate, using a gas dissociation system according to the invention.

FIG. 7 is a graphical representation of percent dissociation of NF₃ as a function of the plasma gas pressure, using a gas dissociation system according to the invention.

FIG. 8 is a graphical representation of percent dissociation of NF₃ as a function of downstream NF₃ flow rate, using a gas dissociation system according to the invention.

FIG. 9 is a graphical representation of percent dissociation of CF₄ as a function of the plasma gas flow rate, using a gas dissociation system according to the invention.

FIG. 10 is a graphical representation of percent dissociation of CF₄ as a function of the plasma gas pressure, using a gas dissociation system according to the invention.

FIG. 11A is a graphical representation of percent dissociation of CHF₃ as a function of the plasma gas flow rate, using a gas dissociation system according to the invention.

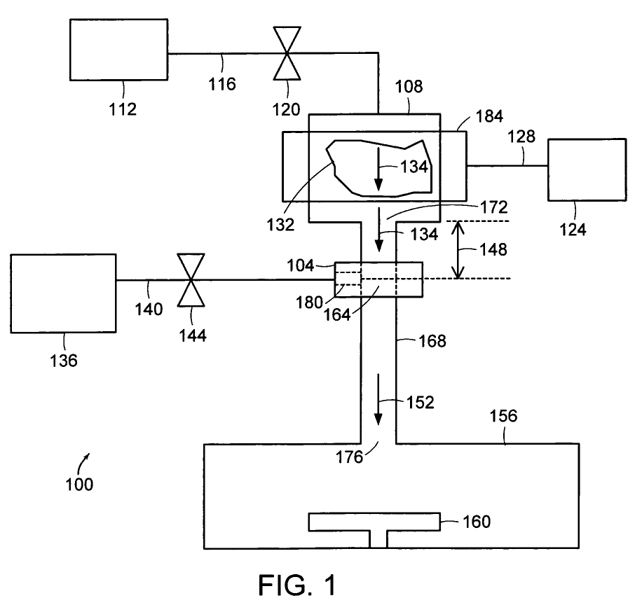

FIG. 1B is a graphical representation of percent dissociation of CHF₃ as a function of the downstream CHF₃ flow rate, using a gas dissociation system according to the invention.

FIG. 12 is a partial schematic view of a plasma source for producing dissociated gases that embodies the invention.

FIG. 13 is a graphical representation of percent dissociation of NF₃ as a function of the distance from the output of a quartz plasma chamber that NF₃ is injected into the plasma source, using a gas dissociation system according to the invention.

FIG. 14 is a cross-sectional view of a portion of a gas injection source, according to an illustrative embodiment of the invention.

### DETAILED DESCRIPTION OF ILLUSTRATIVE EMBODIMENTS

FIG. 1 is partial schematic representation of a gas dissociation system 100 for producing dissociated gases that embodies the invention. Plasmas are often used to activate gases placing them in an excited state such that the gases have an enhanced reactivity. Excitation of a gas involves elevating the energy state of the gas. In some cases, the gases are excited to produce dissociated gases containing ions, free radicals, atoms and molecules. The system 100 includes a plasma gas source 112 connected via a gas line 116 to a plasma chamber 108. A valve 120 controls the flow of plasma gas (e.g., O₂, N₂, Ar, NF₃, H₂ and He) from the plasma gas source 112 through the gas line 116 and into the plasma chamber 108. The valve 120 may be, for example, a solenoid valve, a proportional solenoid valve, or a mass flow controller. A plasma generator 184 generates a region of plasma 132 within the plasma chamber 108. The plasma 132 comprises plasma activated gas 134, a portion of which flows out of the chamber 108. The plasma activated gas 134 is produced as a result of the plasma 132 heating and activating the plasma gas. In this embodiment, the plasma generator 184 is located partially around the plasma chamber 108. The system 100 also includes a power supply 124 that provides power via connection 128 to the plasma generator 184 to generate the plasma 132 (which comprises the activated gas 134) in the plasma chamber 108. The plasma chamber 108 can, for example, be formed from a metallic material such as aluminum or a refractory metal, or can be formed from a dielectric material such as quartz or sapphire. In some embodiments, a gas other than the plasma gas is used to generate the activated gas. In some embodiments, the plasma gas is used to both generate the plasma and to generate the activated gas.

The plasma chamber 108 has an output 172 that is connected via a passage 168 to an input 176 of a process chamber 156. At least a portion of the activated gas 134 flows out of the output 172 of the plasma chamber 108 and through the passage 168. The amount of energy carried in the activated gas 134 decreases with distance along the length of the passage 168. An injection source 104 (e.g., gas injection source) is located at a distance 148 along the length of the passage 168. The injection source 104 can also be located within the lower part of the plasma chamber 108. The gas injection source 104 has at least one gas inlet 180 that introduces gas (e.g., a downstream gas to be dissociated by the activated gas 134) into a region 164 of the passage 168. A downstream gas source 136 introduces the downstream gas (e.g., NF₃, CF₄, CHF₃, C₂F₆, C₂HF₅, C₃F₈, C₄F₈, XeF₂, Cl₂, ClF₃, H₂ or NH₃) through a gas line 140 and through the gas inlet 180 into the region 164 of the passage 168. A valve 144 controls the flow of downstream gas through the gas line 140. The downstream gas can include deposition precursors containing, for example, Si, Ge, Ga, In, As, Sb, Al, Cu, Ta, Ti, Mo, W, Hf, Sr or Zr. The valve 144 may be, for example, a solenoid valve, a proportional solenoid valve, or a mass flow controller.

Downstream gas introduced into the region 164 of the passage 168 at the distance 148 interacts with at least a portion of the activated gas 134 producing a flow of dissociated downstream gas 152. The term “downstream gas” used herein refers to gas introduced into the passage 168 through gas inlet 180. The term “dissociated downstream gas” used herein refers to the gas produced as a result of the activated gas 134 interacting with the downstream gas. The dissociated downstream gas 152 can contain, for example, a mixture of the activated gas 134, the downstream gas, and downstream gas that has been excited (e.g., dissociated) by the activated gas 134. In some embodiments, the dissociated downstream gas 152 contains substantially gas that has been dissociated by the activated gas 134. In other embodiments, the dissociated downstream gas 152 contains, for example, substantially activated gas 134.

The dissociated downstream gas 152 flows through passage 168 and into the input 176 of the process chamber 156. A sample holder 160 positioned in the process chamber 156 supports a material that is processed by the dissociated downstream gas 152. An optional gas distributor or showerhead (not shown) can be installed at the chamber 156 input 176 to uniformly distribute the dissociated gas to the surface of, for example, a substrate located on the holder 160. In one embodiment, the dissociated downstream gas 152 facilitates etching of a semiconductor wafer or substrate located on the sample holder 160 in the process chamber 156. In another embodiment, the dissociated downstream gas 152 facilitates deposition of a thin film on to a substrate located on the sample holder 160 in the process chamber 156. The activated gas 134 has sufficient energy to interact with the downstream gas to produce the dissociated downstream gas 152.

In some embodiments, a percentage of the downstream gas introduced into the region 164 of the passage 168 is dissociated by the activated gas 134. The degree (e.g., percentage) to which the downstream gas is dissociated is a function of, for example, the energy level as well as the amount of energy carried in the activated gas 134. The activated gas 134 can have an energy level greater than the bond energy level of the downstream gas to break the bonds between atoms of the downstream gas to achieve dissociation. In some embodiments, the activated gas 134 can also carry sufficient energy to thermally excite and dissociate the downstream gas through multiple collision processes. By way of example, CF₄ has a bond energy level of about 5.7 eV and NF₃ has a bond energy level of about 3.6 eV. Accordingly, under similar dissociation system 100 operating conditions, higher activated gas 134 energies are required to dissociate CF₄ than is required to dissociate NF₃.

In another embodiment, because the amount of energy contained in the activated gas 134 decreases with distance from the output 172 of the chamber 108 along the passage 168, the distance 148 must be sufficiently small to position the gas inlet 180 relative to the output 172 of the plasma chamber 108 such that the activated gas 134 effectively facilitates excitation (e.g., dissociation) of the downstream gas introduced into the passage 168 by the downstream gas source 104. The distance 148 also must be sufficiently large to position the gas inlet 180 relative to the output 172 of the plasma chamber 108 such that the dissociated downstream gas 152 does not substantially interact with an interior surface of the plasma chamber 108. In some embodiments, the injection source 104 can be located within the lower part of the plasma chamber 108, for example, when the plasma density is concentrated in the upper part of the plasma chamber 108.

In one embodiment, the system 100 includes a barrier (e.g., a shield or liner, not shown) that is located within the passage 168 at the output 172 of the chamber 108. The barrier protects the passage 168 by reducing exposure of the passage 168 to the reactive gases in the system 100. In some embodiments, the shield or liner is located partially within the chamber 108. The shield or liner can be made of a material that is substantially resistant to the reactive gases (e.g., the activated gas 134 and the dissociated downstream gas 152). In this manner, because the shield or liner is exposed to the reactive gases, the shield or liner can be used to reduce erosion of the chamber 108.

In one embodiment, the liner is a tubular material located within the passage 168 at the output 172 of the chamber 108. The liner can be made of a material that is chemically compatible with the reactive gases. The liner can be made completely or partially of sapphire material. In some embodiments, the shield or liner is removable, allowing for periodic replacement. The shield or liner can therefore be made of the same material as the plasma chamber for chemical consistency.

In some embodiments, the shield or liner reduces thermal stresses on components in the chamber 108. The shield or liner can be made of a material that reduces the loss of reactive species in the activated gas 134 and the dissociated downstream gas 152, thereby maximizing the output of the reactive species. Materials with low recombination properties include, for example, quartz, diamond, diamond-like-carbon, sapphire, hydrocarbon and fluorocarbon. The shield or liner can also be made of a metal (e.g., aluminum, nickel or stainless steel) for better mechanical and thermal properties. The surface of a metal shield or liner may be coated with a layer of a chemically compatible or low surface recombination/reaction material to improve the overall performance.

In one embodiment, the system 100 includes an additional purge gas input (not shown) between the output 172 of the plasma chamber 108 and the gas inlet 180. Purge gas can be flowed through the gas inlet 180 to prevent (or minimize) the downstream gas from back streaming into the plasma chamber 108. The back stream may occur when the flow rate of the plasma gas is small. The purge gas can be a noble gas (e.g., Ar or He), or a process gas (e.g., O₂ or H₂).

In one embodiment, the system 100 includes a sensor (not shown) for measuring the percent dissociation of the downstream gas in the passage 168. In certain embodiments, the same sensor is used to determine the degree to which the dissociated downstream gas 152 adversely interacts with the interior surface of the plasma chamber 108. An exemplary sensor for measuring both the percent dissociation and the degree to which the dissociated downstream gas 152 reacts with the interior surface of the chamber 108 is a Nicolet 510P Metrology Tool sold by Thermo Electron Corporation of Madison, Wis. The sensor measures, for example, the presence of SiF₄. SiF₄ is a byproduct of fluorine (a dissociated downstream gas) reacting with a quartz plasma chamber. The sensor is not required; however, it may be used in the system 100. Accordingly, sensor measurements indicating the presence of, for example, high levels of SiF₄ is an indication that the dissociated downstream gas 152 is adversely interacting with the interior surface of a quartz plasma chamber 108. Percent dissociation of the downstream gas depends on a variety of factors. One factor is the distance 148 at which the downstream gas is introduced into the region 164 of the passage 168. Another factor is the amount of energy in the activated gas 134 at the distance 148 at which the downstream gas is introduced into the region 164 of the passage 168.

In one embodiment, the downstream gas is introduced at a distance 148 relative to the output 172 of the plasma chamber 108 that minimizes the interaction between the dissociated gas 152 and the interior surface of the plasma chamber 108. In another embodiment, the downstream gas is introduced at a distance 148 relative to the output 172 of the plasma chamber 108 that maximizes the degree to which the downstream gas is dissociated. In another embodiment, the downstream gas is introduced at a distance 148 relative to the output 172 of the plasma chamber 108 that balances the degree to which the dissociated downstream gas 152 interacts with the interior surface of the plasma chamber 108 with the degree to which the downstream gas is dissociated.

The plasma source 184 can be, for example, a DC plasma generator, radio frequency (RF) plasma generator or a microwave plasma generator. The plasma source 184 can be a remote plasma source. By way of example, the plasma source 184 can be an ASTRON® or a R*evolution® remote plasma source manufactured by MKS Instruments, Inc. of Wilmington, Mass. DC plasma generators produce DC discharges by applying a potential between two electrodes in a plasma gas (e.g., O₂). RF plasma generators produce RF discharges either by electrostatically or inductively coupling energy from a power supply into a plasma. Microwave plasma generators produce microwave discharges by directly coupling microwave energy through a microwave-passing window into a plasma chamber containing a plasma gas.

In one embodiment, the plasma source is a toroidal plasma source and the chamber 108 is a quartz chamber. The quartz chamber can be, for example, a single piece of fused quartz. In other embodiments, alternative types of plasma sources and chamber materials may be used. For example, sapphire, alumina, aluminum nitride, yttrium oxide, silicon carbide, boron nitride, or a metal such as aluminum, nickel or stainless steel, or a coated metal such as anodized aluminum may be used.

The power supply 124 can be, for example, an RF power supply or a microwave power supply. In some embodiments, the plasma chamber 108 includes a means for generating free charges that provides an initial ionization event that ignites the plasma 132 in the plasma chamber 108. The initial ionization event can be a short, high voltage pulse that is applied to the plasma chamber 108. The pulse can have a voltage of approximately 500-10,000 volts and can be approximately 0.1 microseconds to 100 milliseconds long. A noble gas such as argon can be inserted into the plasma chamber 108 to reduce the voltage required to ignite the plasma 132. Ultraviolet radiation also can be used to generate the free charges in the plasma chamber 108 that provide the initial ionization event that ignites the plasma 132 in the plasma chamber 108.

A control system (not shown) can be used to, for example, control the operation of valve 116 (e.g., a mass flow controller) to regulate the flow of the plasma gas from the plasma gas source 112 into the plasma chamber 108. The control system also can be used to control the operation of valve 144 (e.g., a mass flow controller) to regulate the flow of the downstream gas from the downstream gas source 136 into the region 164. The control system also can be used to modify the operating parameters (e.g., power applied to the plasma 132 and subsequently the activated gas 134, or gas flow rates or pressure) of the plasma generator 184.

In some embodiments, the system 100 is contemplated for depositing material on a semiconductor wafer located on the sample holder 160 in the process chamber 156. By way of example, the downstream gas can include a deposition material (e.g., SiH₄, TEOS, or WF₆). The downstream gas can also include other deposition precursors containing, for example, Si, Ge, Ga, In, Sn, As, Sb, Al, Cu, Ta, Ti, Mo, W, Hf, Sr, and Zr. The activated gas 134 interacts with the deposition material in the downstream gas to create a deposition species that may be deposited on the wafer located on the sample holder 160. Exposure of deposition precursors to a plasma may cause precursor molecules to decompose in the gas face. Accordingly, excitation of the precursors by activated gases can be advantageous in applications where decomposition of precursors on a deposition surface is preferred. In some embodiments, the downstream gas includes one or more gases that comprise metallic or semiconductor materials, or oxides or nitrides comprising the metallic or semiconductor materials.

The system 100 can be used to deposit optical coatings on a substrate, such as a mirror, a filter, or a lens. The system 100 can be used to modify surface properties of a substrate. The system 100 can be used to make a surface biocompatible or to change its water absorption properties. The system 100 can be used to generate microscopic or nanoscale particles or powders.

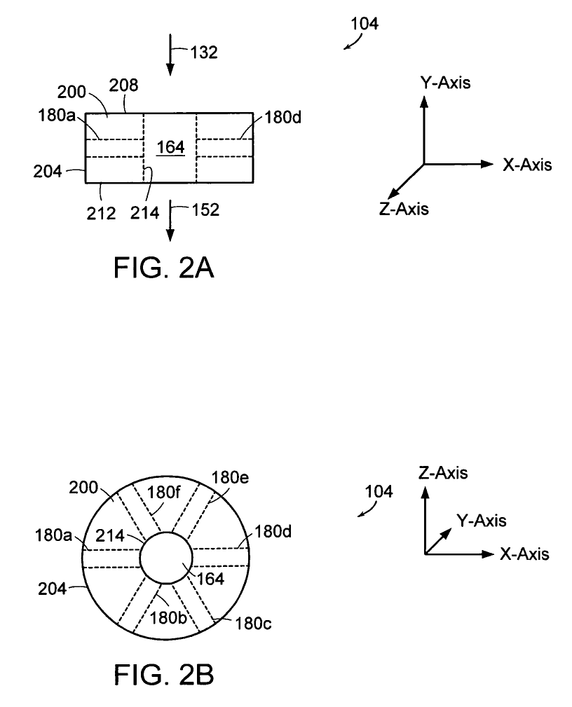

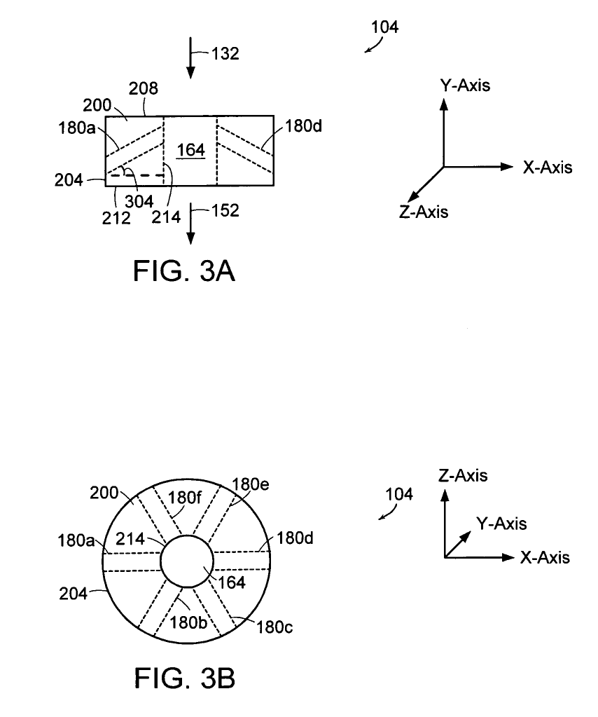

FIGS. 2A and 2B illustrate one embodiment of an injection source 104 incorporating the principals of the invention. In this embodiment, the injection source 104 has a disk-shaped body 200 that defines a central region 164. The region 164 extends from a first end 208 of the body 200 to a second end 212 of the body 200. The source 104 also has six inlets 180a, 180b, 180c, 180d, 180e and 180f (generally 180) that extend through the body 200 of the source 104. The inlets 180 each extend radially from openings in an outer surface 204 of the body 200 to openings along an inner surface 214 of the region 164 of the body 200.

In one embodiment, the inlets 180 are connected to a downstream gas source, for example, the downstream gas source 136 of FIG. 1. The downstream gas source 136 provides a flow of downstream gas via the inlets 180 to the region 164. An activated gas 134 enters the source 104 at the first end 204 of the source 104. At least a portion of the activated gas 134 interacts with at least a portion of the downstream gas to produce a dissociated downstream gas 152. The dissociated downstream gas 152 flows out of the second end 212 of the body 200 of the source 104 and along, for example, the passage 168 of the dissociation system 100. Alternative numbers, geometries and angular orientations of the inlets 180 are contemplated. By way of example, the inlets 180 may be oriented at an angle relative to the center of the region 164 of the body 200 of the source 104 when viewed from the end-view orientation of FIG. 2B.

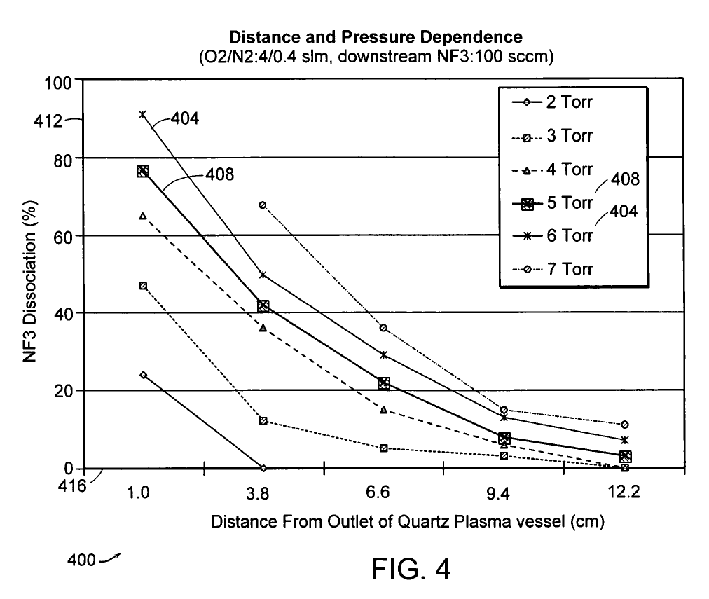

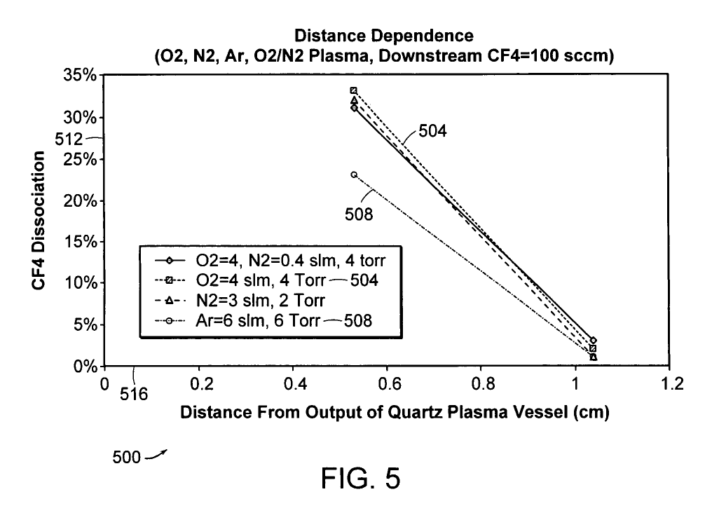

In another embodiment, illustrated in FIGS. 3A and 3B, the injection source 104 has a disk-shaped body 200 that defines a region 164. The body 200 has a first end 208 and a second end 212. The source 104 has six inlets 180a, 180b, 180c, 180d, 180e and 180f (generally 180) that extend through the body 200 of the source 104. Alternate numbers of inlets can be used in other embodiments. The inlets 180 each extend at an angle 304 from openings in an outer surface 204 of the body 200 to openings along an inner surface 214 of the region 164 of the body 200. In one embodiment, the inlets 180 are connected to a downstream gas source, for example, the downstream gas source 136 of FIG. 1. The downstream gas source 136 provides a flow of downstream gas via the inlets 180 to the region 164. The downstream gas is at least partially dissociated by an activated gas 134 that enters the region 164 via the first end 208 of the body 200. Dissociated downstream gas 152 exits the region 164 at the second end 212 of the body 200.

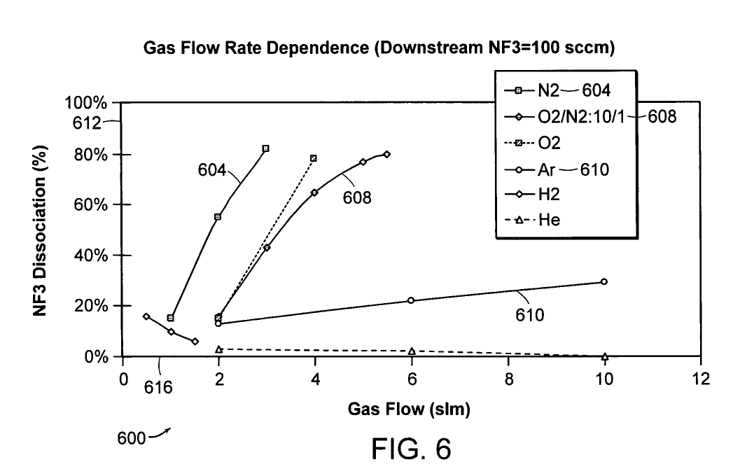

By way of illustration, an experiment was conducted to dissociate NF₃. The injection source 104 of FIGS. 2A and 2B was used to introduce NF₃ into the region 164 of the body 200 of the injection source 104. An inner diameter of about 0.5 mm was selected for each of the inlets 180. FIG. 4 illustrates a plot 400 of the NF₃ dissociation results obtained with a gas dissociation system, such as the gas dissociation system 100 of FIG. 1. The Y-Axis 412 of the plot 400 is the percent dissociation of NF₃. The X-Axis 416 of the plot 400 is the distance 148 that the NF₃ (downstream gas) is injected into the region 164 relative to the output 172 of a quartz plasma chamber 108.

FIG. 4 shows that at fixed flow rates of plasma gas (O₂/N₂) and downstream gas (NF₃), the percent dissociation of NF₃ increases with gas pressure and decreases with the distance from the outlet of the plasma chamber. As the distance 148 increases the percent dissociation of NF₃ decreases for a specified plasma gas pressure level (2 Torr; 3 Torr; 4 Torr; 5 Torr (curve 408); 6 Torr (curve 404); 7 Torr). By way of illustration, curve 404 shows that for an O₂/N₂ plasma gas flow rate of 4/0.4 slm into the plasma chamber 108 at a plasma gas pressure of 6 Torr, the percent dissociation of NF₃ decreases from about 92% dissociation of NF₃ at a distance 148 equal to about 1.0 cm to about 8% dissociation of NF₃ at distance 148 equal to about 12.2 cm. Curve 408 shows that for an O₂/N₂ plasma gas flow rate of 4/0.4 slm into the plasma chamber 108 at a plasma gas pressure of 5 Torr, the percent dissociation of NF₃ decreases from about 77% dissociation of NF₃ at a distance 148 equal to about 1.0 cm to about 3% dissociation of NF₃ at a distance 148 equal to about 12.2 cm.

In the experiment, minimal adverse effects of the dissociated downstream gas 152 on the quartz chamber 108 were measured using the Nicolet 510P sensor described previously herein. The Nicolet 510P sensor had a detection sensitivity of 1 sccm of SiF₄. In the experiment, no SiF₄ was measured using the Nicolet sensor for the various plasma gas pressures and distances 148 that the NF₃ (downstream gas) is injected into the region 164 relative to the output 172 of a quartz plasma chamber 108.

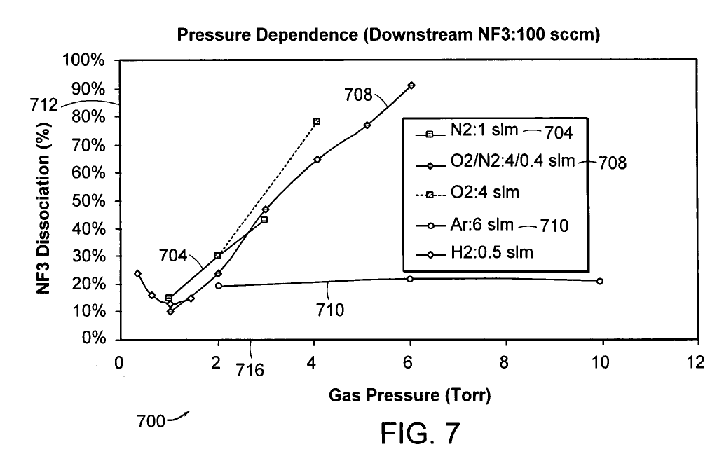

By way of illustration, an experiment was conducted to dissociate CF₄. The injection source 104 of FIGS. 3A and 3B was used to introduce CF₄ into the region 164 of the body 200 of the injection source 104. An inner diameter of about 0.5 mm was selected for each of the inlets 180. An angle of 30° was selected for the angle 304 for each of the inlets 180. FIG. 5 illustrates a plot 500 of the CF₄ dissociation results obtained with a gas dissociation system, such as the gas dissociation system 100 of FIG. 1. The Y-Axis 512 of the plot 500 is the percent dissociation of CF₄. The X-Axis 516 of the plot 500 is the distance 148 that the CF₄ (downstream gas) is injected into the region 164 of the passage 168 relative to the output 172 of a quartz plasma chamber 108.

FIG. 5 shows that as the distance 148 increases the percent dissociation of CF₄ decreases for various plasma gas types, flow rates and pressures (4 slm of O₂ mixed with 0.4 slm of N₂ at 4 Torr; 4 slm of O₂ at 4 Torr (curve 504); 3 slm of N₂ at 2 Torr; and 6 slm of Ar at 6 Torr (curve 508)). By way of illustration, curve 504 shows that for an O₂ plasma gas flow from the plasma gas source 112 at a rate of 4 slm at a pressure of 4 Torr in the plasma chamber 108, the percent dissociation of 100 sccm of CF₄ decreases from about 33% dissociation of CF₄ at a distance 148 equal to about 0.53 cm to about 2% dissociation of CF₄ at a distance 148 equal to about 1.05 cm. Curve 508 shows that for an Ar plasma gas flow rate of 6 slm into the plasma chamber 108 at a pressure of 6 Torr, the percent dissociation of CF₄ decreases from about 24% dissociation of CF₄ at a distance 148 equal to about 0.53 cm to about 1% dissociation of CF₄ at a distance 148 equal to about 1.05 cm.

In the experiment, minimal adverse effects of the dissociated downstream gas 152 on the quartz chamber 108 were measured using the Nicolet 510P sensor described previously herein. In the experiment, no SiF₄ was measured using the Nicolet sensor for the various plasma gas types, flow rates, pressures and distances 148 that the CF₄ (downstream gas) is injected into the region 164 relative to the output 172 of a quartz plasma chamber 108.

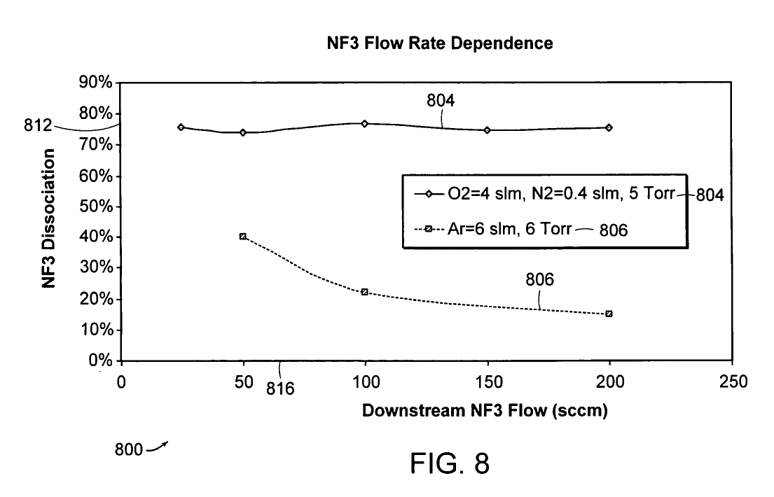

Another experiment was conducted to dissociate NF₃. The injection source 104 of FIGS. 2A and 2B was used to introduce 100 sccm of NF₃ into the region 164 of the body 200 of the injection source 104. An inner diameter of about 0.5 mm was selected for each of the inlets 180. The downstream gas (NF₃) is introduced into the region 164 of the passage 168 at about 1 cm (i.e., the distance 148) relative to the output 172 of the quartz plasma chamber 108. FIG. 6 illustrates a plot 600 of the NF₃ dissociation results obtained with a gas dissociation system, such as the gas dissociation system 100 of FIG. 1. The Y-Axis 612 of the plot 600 is the percent dissociation of NF₃. The X-Axis 616 of the plot 600 is the gas flow rate in standard liters per minute of the plasma gas (N₂ (curve 604); O₂/N₂ at a gas flow ration of 10/1 (curve 608); Ar (curve 610); H₂; and He) that is introduced into the chamber 108 by the plasma gas source 112.

By way of illustration, curve 604 shows that for an N₂ plasma gas, the percent dissociation of 100 sccm of NF₃ increases from about 16% dissociation of NF₃ at an N₂ plasma gas flow rate of about 1.0 slm to about 82% dissociation of NF₃ at an N₂ plasma gas flow rate of about 2.3 slm. Curve 608 shows that for an O₂/N₂ plasma gas, the percent dissociation of 100 sccm of NF₃ increases from about 16% dissociation of NF₃ at an O₂/N₂ gas flow rate of 2/0.2 slm to about 79% dissociation of NF₃ at an O₂/N₂ gas flow rate of about 5.5/0.55 slm. Curve 610 shows that for an Ar plasma gas, the percent dissociation of a flow of 100 sccm of NF₃ increases from about 14% dissociation of NF₃ at an Ar plasma gas flow rate of about 2.0 slm to about 29% dissociation of NF₃ at an Ar plasma gas flow rate of about 10 slm.

In the experiment, minimal adverse effects of the dissociated downstream gas 152 on the quartz chamber 108 were measured using the Nicolet 510P sensor described previously herein. In the experiment, no SiF₄ was measured using the Nicolet sensor for the various plasma gas types and flow rates.

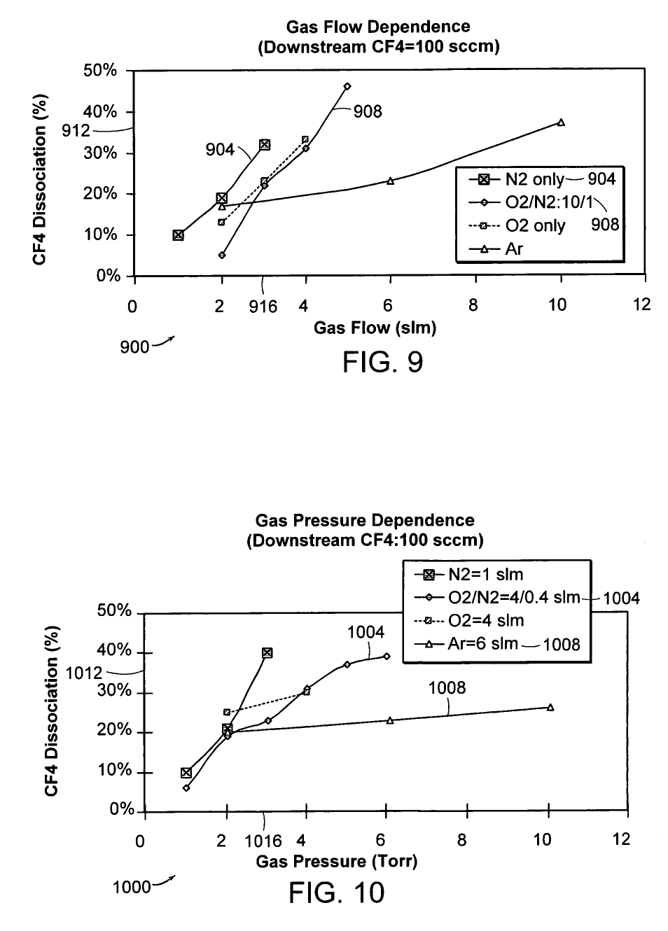

Another experiment was conducted to dissociate NF₃. The injection source 104 of FIGS. 2A and 2B was used to introduce 100 sccm of NF₃ into the region 164 of the body 200 of the injection source 104. An inner diameter of about 0.5 mm was selected for each of the inlets 180. The downstream gas (NF₃) is introduced at about 1.0 cm (i.e., the distance 148) relative to the output 172 of the plasma chamber 108. FIG. 7 illustrates a plot 700 of the NF₃ dissociation results obtained with a gas dissociation system, such as the gas dissociation system 100 of FIG. 1. The Y-Axis 712 of the plot 700 is the percent dissociation of NF₃. The X-Axis 716 of the plot 700 is the gas pressure in Torr of the plasma gas introduced into the plasma chamber 108. Under the operating conditions of the experiment, the percent dissociation of NF₃ using an Ar plasma gas (shown as curve 710) is relatively insensitive to Ar gas pressure.

By way of illustration, curve 704 shows that for an N₂ plasma gas flow of 1 slm, the percent dissociation of 100 sccm of NF₃ increases from about 15% dissociation of NF₃ at a plasma gas pressure of 1 Torr to about 42% dissociation of NF₃ at a plasma gas pressure of 3 Torr. Curve 708 shows that for an O₂/N₂ plasma gas flow of 4/0.4 slm, the percent dissociation of 100 sccm of NF₃ increases from about 10% dissociation of NF₃ at a plasma gas pressure of 1 Torr to about 90% dissociation of NF₃ at a plasma gas pressure of 6 Torr. Curve 710 shows that for an Ar plasma gas flow of 6 slm, the percent dissociation of 100 sccm of NF₃ is about 19% at a plasma gas pressure of 2 Torr, 22% at a plasma gas pressure of 6 Torr, and about 21% at a plasma gas pressure of 10 Torr.

In the experiment, minimal adverse effects of the dissociated downstream gas 152 on the quartz chamber 108 were measured using the Nicolet 510P sensor described previously herein. In the experiment, no SiF₄ was measured using the Nicolet sensor for the various plasma gas types, flow rates and pressures.

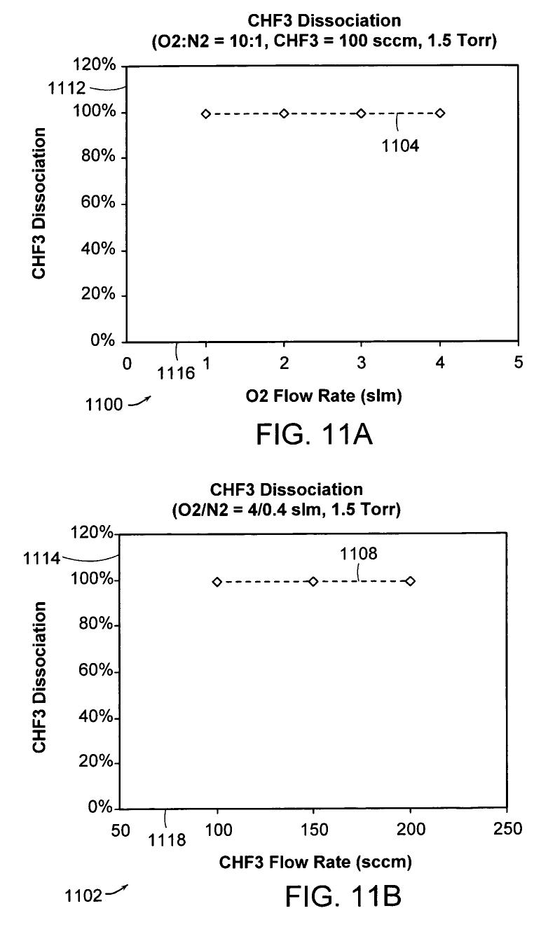

Another experiment was conducted to dissociate NF₃. The injection source 104 of FIGS. 2A and 2B was used to introduce NF₃ into the region 164 of the body 200 of the injection source 104. An inner diameter of about 0.5 mm was selected for each of the inlets 180. The downstream gas (NF₃) is introduced at about 1 cm (i.e., the distance 148) relative to the output 172 of the plasma chamber 108. FIG. 8 illustrates plot 800 of the NF₃ dissociation results obtained with a gas dissociation system, such as the gas dissociation system 100 of FIG. 1. The Y-Axis 812 of the plot 800 is the percent dissociation of NF₃. The X-Axis 816 of the plot 800 is the downstream NF₃ flow rate in sccm.

Curve 804 of plot 800 of FIG. 8 shows that for an O₂/N₂ plasma gas at a flow rate of 4/0.4 slm and a pressure of 5 Torr, the percent dissociation of NF₃ remains at about 75% from a flow rate of NF₃ of about 25 sccm to a flow rate of NF₃ of about 200 sccm. It shows that under these operating conditions the percent dissociation of NF₃ is relatively insensitive to the flow rate of NF₃ as evidenced by the relatively constant percent dissociation of NF₃ (curve 804). Curve 806 of plot 800 of FIG. 8 shows that for an Ar plasma gas at a flow rate of about 6 slm and a pressure of 6 Torr, the percent dissociation of NF₃ decreases from about 40% at a flow rate of NF₃ of about 50 sccm to about 15% at a flow rate of NF₃ of about 200 sccm.

In the experiment, minimal adverse effects of the dissociated downstream gas 152 on the quartz chamber 108 were measured using the Nicolet 510P sensor described previously herein. In the experiment, no SiF₄ was measured using the Nicolet sensor for the various gas dissociation system 100 operating conditions.

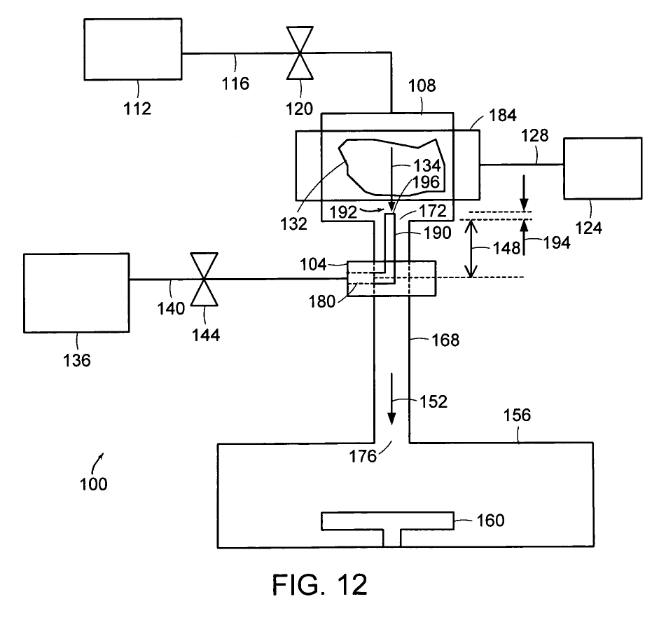

By way of illustration, another experiment was conducted to dissociate CF₄. The injection source 104 of FIGS. 3A and 3B was used to introduce 100 sccm of CF₄ into the region 164 of the body 200 of the injection source 104. An inner diameter of about 0.5 mm was selected for each of the inlets 180. An angle of 30° was selected for the angle 304 for each of the inlets 180. The downstream gas (CF₄) is introduced at about 0.5 cm (i.e., the distance 148) relative to the output 172 of the plasma chamber 108. FIG. 9 illustrates a plot 900 of the CF₄ dissociation results obtained with a gas dissociation system, such as the gas dissociation system 100 of FIG. 1. The Y-Axis 912 of the plot 900 is the percent dissociation of CF₄. The X-Axis 916 of the plot 900 is the gas flow rate in standard liters per minute of the plasma gas (N₂ (curve 904); O₂/N₂ (curve 908); O₂; and Ar) that is introduced into the chamber 108 by the plasma gas source 112.

FIG. 9 shows that at 100 sccm of downstream CF₄ flow the percent dissociation of CF₄ increases as the plasma gas flow rate increases. By way of illustration, curve 904 shows that for an N₂ plasma gas, the percent dissociation of a flow of 100 standard cubic centimeters per minute of CF₄ increases from about 10% dissociation of CF₄ at an N₂ plasma gas flow rate of about 1.0 slm to about 32% dissociation of CF₄ at an N₂ plasma gas flow rate of about 3 slm. Curve 908 shows that for an O₂/N₂ plasma gas, the percent dissociation of a flow of 100 sccm of CF₄ increases from about 5% dissociation of CF₄ at an O₂/N₂ plasma gas flow rate of about 2.0/0.2 slm to about 46% dissociation of CF₄ at an O₂/N₂ plasma gas flow rate of about 5.0/0.5 slm.

In the experiment, minimal adverse effects of the dissociated downstream gas 152 on the quartz chamber 108 were measured using the Nicolet 510P sensor described previously herein. In the experiment, no SiF₄ was measured using the Nicolet sensor for the various plasma gas types and flow rates.

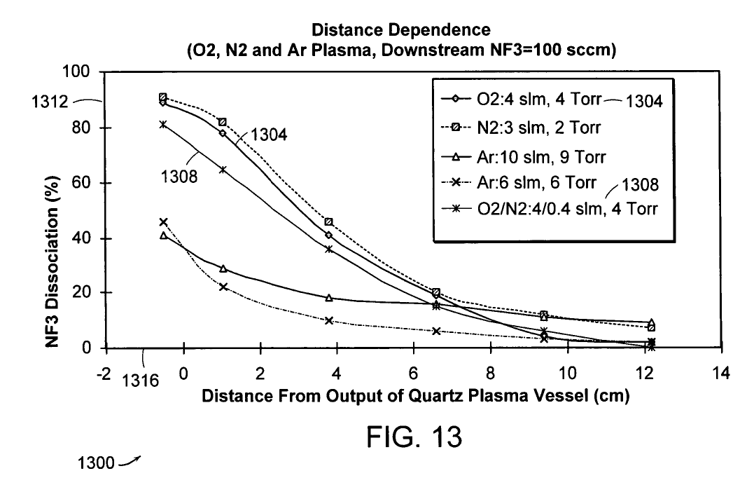

By way of illustration, another experiment was conducted to dissociate CF₄. The injection source 104 of FIGS. 3A and 3B was used to introduce 100 sccm of CF₄ into the region 164 of the body 200 of the injection source 104. An inner diameter of about 0.5 mm was selected for each of the inlets 180. An angle of 30° was selected for the angle 304 for each of the inlets 180. The downstream gas (CF₄) is introduced at about 0.5 cm (i.e., the distance 148) relative to the output 172 of the plasma chamber 108. FIG. 10 illustrates a plot 1000 of the CF₄ dissociation results obtained with a gas dissociation system, such as the gas dissociation system 100 of FIG. 1. The Y-Axis 1012 of the plot 1000 is the percent dissociation of CF₄. The X-Axis 1016 of the plot 1000 is the gas pressure in Torr of the plasma gas (1 slm of N₂; 4/0.4 slm of O₂/N₂ (curve 1004); 4 slm of O₂; and 6 slm of Ar (curve 1008)).

Curve 1004 shows that for an O₂/N₂ plasma gas flow of 4/0.4 slm, the percent dissociation of a flow of 100 standard cubic centimeters per minute of CF₄ increases from about 5% dissociation of CF₄ at a plasma gas pressure of 1.0 Torr to about 39% dissociation of CF₄ at a plasma gas pressure of 6 Torr. Curve 1008 shows that for an Ar plasma gas flow of 6 slm, the percent dissociation of a flow of 100 standard cubic centimeters per minute of CF₄ increases from about 20% dissociation of CF₄ at a plasma gas pressure of 2.0 Torr to about 25% dissociation of CF₄ at a plasma gas pressure of 10 Torr.

In the experiment, minimal adverse effects of the dissociated downstream gas 152 on the quartz chamber 108 were measured using the Nicolet 510P sensor described previously herein. In the experiment, no SiF₄ was measured using the Nicolet sensor for the various plasma gas types, flow rates and pressures.

By way of illustration, another experiment was conducted to dissociate CHF₃. The injection source 104 of FIGS. 3A and 3B was used to introduce CHF₃ into the region 164 of the body 200 of the injection source 104. An inner diameter of about 0.5 mm was selected for each of the inlets 180. An angle of 30° was selected for the angle 304 for each of the inlets 180. The downstream gas (CHF₃) is introduced at about 0.5 cm (i.e., the distance 148) relative to the output 172 of the plasma chamber 108.

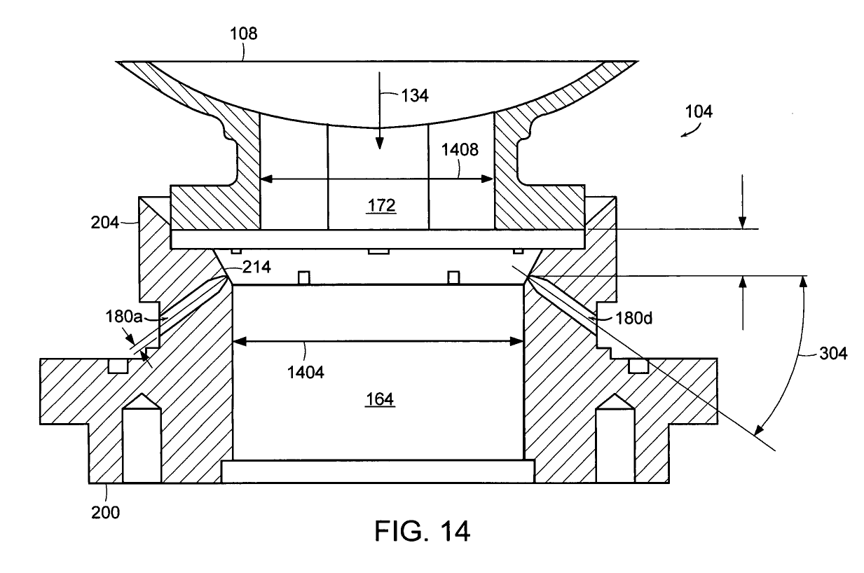

FIG. 11A illustrates a plot 1100 of the CHF₃ dissociation results obtained with a gas dissociation system, such as the gas dissociation system 100 of FIG. 1. The plasma gas is an O₂/N₂ mixture at an O₂ to N₂ ratio of 10:1. The Y-Axis 1112 of the plot 1100 is the percent dissociation of CHF₃. The X-Axis 1116 of the plot 1100 is the gas flow rate in standard liters per minute of the O₂ in the plasma gas that is introduced into the chamber 108 by the plasma gas source 112. Curve 1104 of FIG. 11A shows that for a plasma gas pressure of 1.5 Torr and a downstream CHF₃ flow of 100 sccm, nearly 100% dissociation of CHF₃ is obtained with the flow rate of O₂ in the plasma gas ranging from 1 slm to 4 slm.

FIG. 11B illustrates a plot 1102 of the CHF₃ dissociation results obtained with a gas dissociation system, such as the gas dissociation system 100 of FIG. 1. The Y-Axis 1114 of the plot 1102 is the percent dissociation of CHF₃. The X-Axis 1118 of the plot 1102 is the flow rate of downstream CHF₃ in sccm. Curve 1108 of FIG. 11B shows that for a plasma gas flow rate of 4 slm of O₂ and 0.4 slm of N₂ at a pressure of 1.5 Torr, nearly 100% dissociation of CHF₃ is obtained with the downstream CHF₃ flow rate ranging from 100 sccm to 200 sccm.

In the experiments, minimal adverse effects of the dissociated downstream gas 152 on the quartz chamber 108 were measured using the Nicolet 510P sensor described previously herein. In the experiment, no SiF₄ was measured using the Nicolet sensor for the various plasma gas pressures and distances 148 that the CHF₃ (downstream gas) is injected into the region 164 relative to the output 172 of a quartz plasma chamber 108.

In another embodiment, illustrated in FIG. 12, the system 100 includes a plasma gas source 112 connected via a gas line 116 to a plasma chamber 108. A plasma generator 184 generates a plasma region 132 within the plasma chamber 108. The plasma 132 comprises a plasma activated gas 134, a portion of which flows out of the plasma region 132. The system 100 includes an injection source 104. In this embodiment, the injection source 104 includes an L-shaped pipe 190 that is coupled to a gas inlet of the injection source 104. The pipe 190 introduces a gas (e.g., a downstream gas to be dissociated by the activated gas 134) into a region 192 of the system 100. The region 192 (i.e., the location at which the activated gas 134 interacts with the downstream gas) depends on where an output 196 of the pipe 190 is located. The output 196 of the pipe 190 may be located, for example, at a distance 194 within the output 172 of the plasma chamber 108. The output 196 of the pipe 190 may, alternatively, be located at a distance outside the output 172 of the chamber 108 if, for example, the injection source 104 is instead moved in a direction away from the output 172 and towards the process chamber 156. In this manner, the downstream gas may be introduced into the system 100 inside or outside the plasma chamber 108.

By way of illustration, an experiment was conducted to dissociate NF₃. The injection source 104 of FIG. 12 was used to introduce NF₃ into the region 192 of the system 100. FIG. 13 illustrates a plot 1300 of the NF₃ dissociation results obtained with a gas dissociation system, such as the gas dissociation system 100 of FIG. 12. The Y-Axis 1312 of the plot 1300 is the percent dissociation of NF₃. The X-Axis 1316 of the plot 1300 is the distance that the NF₃ (downstream gas) is injected into the region 192 relative to the output 172 of a quartz plasma chamber 108. In this experiment, during one test the NF₃ was injected at a distance 194 of about 0.5 cm within the output 172 of the chamber 108. The NF₃ also was injected during additional tests at distance 148 (about 1.0 cm, 3.8 cm, 6.6 cm, 9.4 cm, and 12.2 cm) outside the output 172 of the chamber 108.

FIG. 13 shows that the percent dissociation of NF₃ decreases for various plasma gas types, flow rates, and pressures (4 standard liters per minute (slm) of O₂ at 4 Torr (curve 1304); 3 slm of N₂ at 2 Torr; 10 slm of Ar at 9 Torr; 6 slm of Ar at 6 Torr; and 4 slm of O₂ mixed with 0.4 slm of N₂ at 4 Torr (curve 1308)). By way of illustration, curve 1304 shows that for an O₂ plasma gas flow from the plasma gas source 112 at a rate of 4 standard liters per minute (slm) at a pressure of 4 Torr in the plasma chamber 108, the percent dissociation of 100 standard cubic centimeters per minute (sccm) of NF₃ decreases from about 90% dissociation of NF₃ at a distance 194 equal to about 0.5 cm to about 2% dissociation of NF₃ at a distance 148 equal to about 12.2 cm. Curve 1308 shows that for an O₂/N₂ plasma gas flow rate of 4/0.4 slm into the plasma chamber 108 at a pressure of 4 Torr, the percent dissociation of NF₃ decreases from about 81 % dissociation of NF₃ at a distance 194 equal to about 0.5 cm to about 0% dissociation of NF₃ at a distance 148 equal to about 12.2 cm.

In the experiment, minimal adverse effects of the dissociated downstream gas 152 on the quartz chamber 108 were measured using the Nicolet 510P sensor described previously herein. In the experiment, no SiF₄ was measured using the Nicolet sensor for the various plasma gas pressures and distances 194 and 148 that the NF₃ (downstream gas) is injected into the region 192 relative to the output 172 of a quartz plasma chamber 108.

FIG. 14 is a schematic cross-sectional view of a portion of a gas dissociation system (e.g., the system 100 of FIG. 1) including an injection source 104 used in producing dissociated gases that embodies the invention. A body 200 of the injection source 104 is connected to the output 172 of the plasma chamber 108 (only a portion of the chamber 108 is shown for clarity of illustration purposes). The source 104 has six inlets 180a, 180b, 180c, 180d, 180e and 180f (generally 180) that extend through the body 200 of the source 104. Inlets 180b, 180c, 180e and 180f are not shown for clarity of illustration purposes. The inlets 180 each extend at an angle 304 from openings in an outer surface 204 of the body 200 to openings along an inner surface 214 of the region 164 of the body 200. The inlets 180 are connected to a downstream gas source (e.g., the gas source 136 of FIG. 1) to provide a flow of downstream gas via the inlets 180 to the region 164.

Plasma activated gas 134 enters the region 164 through the output 172 of the plasma chamber 108. Reactions between the downstream gas and plasma activated gas 134 occur when the two gas streams are mixed. Enhancing the mixing of the gases improves the dissociation of the downstream gas. In some embodiments, it is beneficial for the gas mixing to occur close to the plasma chamber output 172. In this manner, the mixing can have a minimal effect on the dissociated gas when it enters, for example, a process chamber.

Various static flow mixers, such as helical mixers, blades, and stacked cylinder mixers, can be used to mix the downstream gas and the plasma activated gas 134. Referring to FIG. 14, in this embodiment, the diameter 1404 of region 164 is larger then the diameter 1408 of the plasma chamber output 172. A sudden expansion of the diameter of the flow passage due to a transition in diameter 1408 of the outlet 1408 to diameter 1404 of region 164 creates turbulence and gas recirculation in the region 164 in the wake of the activated gas flow 134. The enhanced mixing from the turbulence and recirculation improved the dissociation of the downstream gas.

Variations, modifications, and other implementations of what is described herein will occur to those of ordinary skill in the art without departing from the spirit and the scope of the invention as claimed. Accordingly, the invention is to be defined not by the preceding illustrative description but instead by the spirit and scope of the following claims.

What is claimed is:

1. A method for depositing a material on a substrate, comprising:
generating an activated gas with a plasma in a chamber; and
positioning a downstream gas input relative to an output of the chamber to enable the activated gas to facilitate dissociation of a downstream gas which is introduced by the gas input, wherein the downstream gas comprises a material to be deposited, and wherein the dissociated downstream gas does not substantially interact with an interior surface of the chamber.

2. The method of claim 1 wherein the plasma is generated by a remote plasma source.

3. The method of claim 1 wherein the remote plasma source is a remote plasma source selected from the group consisting of an RF plasma generator, a microwave plasma generator, and a DC plasma generator.

4. The method of claim 1 wherein the downstream gas is introduced at a location relative to the output of the chamber that minimizes the interaction between the dissociated downstream gas and the interior surface of the chamber.

5. The method of claim 1 wherein the downstream gas is introduced at a location relative to the output of the chamber that maximizes the degree to which the downstream gas is dissociated.

6. The method of claim 1 wherein the downstream gas is introduced at a location relative to the output of the chamber that balances the degree to which the dissociated downstream gas interacts with the interior surface of the chamber with the degree to which the downstream gas is dissociated.

7. The method of claim 1 wherein the material to be deposited comprises one or more of Si, Ge, Ga, In, As, Sb, Ta, W, Mo, Ti, Hf, Zr, Cu, Sr or Al.

8. The method of claim 1 wherein the downstream gas is introduced at a location relative to the output of the chamber that balances the degree to which the dissociated downstream gas interacts with the interior surface of the chamber with the degree to which the downstream gas is dissociated.

9. A system for depositing a material on a substrate, comprising:
a remote plasma source for generating a plasma region in a chamber, wherein the plasma generates an activated gas; and
an injection source for introducing a downstream gas, comprising a deposition material, to interact with the activated gas outside the plasma region, wherein the activated gas facilitates excitation of the downstream gas, and wherein the excited downstream gas does not substantially interact with an interior surface of the chamber.

10. The system of claim 9 wherein excitation of the downstream gas comprises dissociating the downstream gas.

11. The system of claim 9 wherein the deposition material comprises one or more of Si, Ge, Ga, In, As, Sb, Ta, W, Mo, Ti, Hf, Zr, Cu, Sr or Al.

12. The system of claim 9 comprising a mixer to mix downstream gas and activated gas.

13. The system of claim 12 wherein the mixer comprises a static flow mixer, a helical mixer, blades, or a stacked cylinder mixer.

14. The system of claim 9 comprising a purge gas input.

15. The system of claim 14 wherein the purge gas input is located between an outlet of the chamber and an input of the injection source.
